(19) United States
(12) Patent Application Publication
(10) Pub. No.: US 2020/0247084 A1
(43) Pub. Date: Aug. 6, 2020

(54) LAMINATE EXHIBITING STRUCTURAL COLOR

(71) Applicant: NATIONAL UNIVERISTY CORPORATION KOBE UNIVERSITY, Hyogo (JP)

(72) Inventors: Kanna AOKI, Hyogo (JP); Takayuki YONEYAMA, Hyogo (JP); Takayuki SHIGA, Hyogo (JP)

(73) Assignee: NATIONAL UNIVERSITY CORPORATION KOBE UNIVERSITY, Hyogo (JP)

(21) Appl. No.: 16/492,508

(22) PCT Filed: Mar. 8, 2018
(86) PCT No.: PCT/JP2018/008936

§ 371 Date: Feb. 28, 2020

(30) Foreign Application Priority Data
Mar. 8, 2017 (JP) 2017-043572

(51) Int. Cl. B32B 3/30; B32B 15/04; C23C 14/06

(52) U.S. Cl. CPC B32B 3/30; B82Y 20/00; C23C 14/06; B32B 15/04

(57) ABSTRACT

A laminate exhibiting structural color is characterized by including: a base material layer having a plurality of projections or a plurality of recesses substantially regularly arranged on a surface thereof; a first layer that is a metal layer laminated on the surface of the base material layer so as to have a metallic microstructure enabling surface plasmonic resonance; and a second layer laminated on the first layer and made of a material that more easily absorbs visible light than a metal forming the first layer.

### TECHNICAL FIELD

The present invention relates to a laminate exhibiting structural color.

### BACKGROUND ART

It is known that fine metal particles have a phenomenon of absorbing light of a specific wavelength in incident light due to resonance (surface plasmonic resonance) of vibration of incident light and electrons in the fine metal particles. Such a phenomenon is used, for example, for color development of stained glass. In stained glass, a metallic microstructure is provided in glass by mixing specific fine metal particles, and structural color is developed due to the presence of the metallic microstructure.

The structural color developed by such a metallic microstructure does not fade unlike color developed by a pigment or dye, and thus is expected to be applied to decorative members.

As a color-developing material using structural color developed by a metallic microstructure, in addition to one using fine metal particles, for example, a member that exhibits structural color by an uneven metallic microstructure provided by forming a periodic array structure of nanoparticles on a glass substrate and laminating an aluminum thin film thereon has been proposed (see, for example, NON PATENT LITERATURE 1).

### CITATION LIST

### Non Patent Literature

NON PATENT LITERATURE 1; Takayuki Yoneyama and two others, “Structural Color Generation Based on Surface Plasmonic Resonance Using Self-assembled Arrays of Charged Nano-sphere”, the 63rd Japan Society of Applied Physics Spring Meeting (2016) proceedings

### SUMMARY OF INVENTION

### Technical Problem

There is a high demand for developing more colorful and brilliant colors for such a member exhibiting structural color, and there is room for improvement in this respect.

The present inventors have conducted an intensive study to meet the above demand and completed the present invention.

### Solution to Problem

(1) A laminate exhibiting structural color according to the present invention includes:

a base material layer having a plurality of projections or a plurality of recesses substantially regularly arranged thereon;

a first layer that is a metal layer laminated on the base material layer so as to have a metallic microstructure enabling surface plasmonic resonance; and

a second layer laminated on the first layer and made of a material that more easily absorbs visible light than a metal forming the first layer.

In the laminate exhibiting the structural color, the second layer made of the material that more easily absorbs visible light than the metal forming the first layer is further laminated on a laminate of the base material layer and the first layer that can develop the structural color by itself. Thus, the saturation of the structural color can be significantly improved as compared to the case where the second layer is not laminated.
(2) In the laminate exhibiting the structural color, a height of each projection or a depth of each recess of the base material layer is preferably 100 to 900 nm.

This is because this case is suitable for exhibiting the structural color.
(3) In the laminate exhibiting the structural color, preferably,

the plurality of projections each have a spherical shape, and

each projection is composed of a fine particle having a diameter of 100 to 900 nm.

The base material layer having such projections can be produced by a simple method without using an expensive apparatus or facility.

Moreover, the base material layer can easily have a metallic microstructure by covering the upper surfaces of the fine particles with the first layer, and is suitable as a base material layer for a laminate exhibiting structural color.
(4) In the laminate exhibiting the structural color, a thickness of the first layer is preferably 20 to 300 nm.

The first layer having such a thickness is suitable for causing surface plasmonic resonance.
(5) In the laminate exhibiting the structural color, the first layer is preferably made of aluminum, gold, silver, copper, or titanium, or an alloy thereof.

The first layer made of the metallic material easily reflects visible light. Thus, by including such a first layer, the effect of interference between light reflected on the surface of the first layer formed on the upper surface of the base material layer at which the projections are not formed and light reflected on the surface of the first layer formed on the upper surface of each projection becomes remarkable. As a result, the brightness of the structural color can be improved.
(6) In the laminate exhibiting the structural color, the second layer preferably has a reflectance for visible light of 75% or less.

The second layer having such a reflectance for visible light absorbs visible light and is suitable as a second layer that improves the saturation of the structural color.
(7) In the laminate exhibiting the structural color, the second layer is preferably made of germanium, chromium, carbon, or a compound of chromium or carbon.

The reason for this is as follows. The film surface of the first layer made of aluminum or silver and formed by vapor deposition or sputtering usually has a roughness of about 20 nm. Thus, incident light is not only regularly reflected but also irregularly reflected on the surface of the first layer. In this case, light of all wavelengths is mixed by irregular reflection, so that the color of the structural color is close to white light.

On the other hand, the second layer made of germanium, chromium, carbon, or a compound of chromium or carbon absorbs light in the entire visible light range. Thus, if the second layer is thinly formed on the surface of the first layer made of aluminum or silver, the second layer absorbs regularly reflected light and irregularly reflected light on the surface of the first layer and is suitable for improving the saturation of the structural color.

The reason why absorption of regularly reflected light and irregularly reflected light on the surface of the first layer improves the saturation of the structural color, is that the intensity of the regularly reflected light is stronger than the intensity of the irregularly reflected light, and the regularly reflected light mainly remains as a result of the light being absorbed by the second layer.
(8) In the laminate exhibiting the structural color, a thickness of the second layer is preferably 3 to 13 nm.

This is because, in this case, the saturation of the structural color exhibited by the laminate can be improved without decreasing the brightness of the structural color or changing the hue of the structural color.
(9) In the laminate exhibiting the structural color, a transparent protective layer is preferably further provided at an outermost layer.

In this case, irregular reflection of light on the surfaces of the first layer and the second layer can be suppressed, and the durability of the laminate can be improved.

### Advantageous Effects of Invention

According to the present invention, a laminate exhibiting structural color having excellent saturation can be provided.

### BRIEF DESCRIPTION OF DRAWINGS

FIG. 1 is a cross-sectional view schematically showing a laminate exhibiting structural color according to a first embodiment.

FIG. 2 is a plan view showing a part of a base material layer forming a part of the laminate exhibiting the structural color shown in FIG. 1.

FIG. 3 is a cross-sectional view schematically showing a laminate exhibiting structural color according to a second embodiment.

FIG. 4 is a cross-sectional view schematically showing a laminate exhibiting structural color according to a third embodiment.

FIG. 5 is a plan view schematically showing a laminate exhibiting structural color according to a fourth embodiment.

FIG. 6(a) to FIG. 6(c) show evaluation results of laminates exhibiting structural color produced in Test Examples 1 to 8.

FIG. 7 is a diagram for explaining a position for taking a color photograph in evaluation of the Test Examples.

FIG. 8 is an electron micrograph of a base material layer produced in Test Example 9 and a first layer laminated on the base material layer.

FIG. 9(a) and FIG. 9(b) show evaluation results of laminates exhibiting structural color produced in Test Examples 9 to 16.

FIG. 10(a) to FIG. 10(c) show evaluation results of laminates exhibiting structural color produced in Test Examples 17 to 24.

### DESCRIPTION OF EMBODIMENTS

Hereinafter, embodiments of the present invention will be described with reference to the drawings.

### First Embodiment

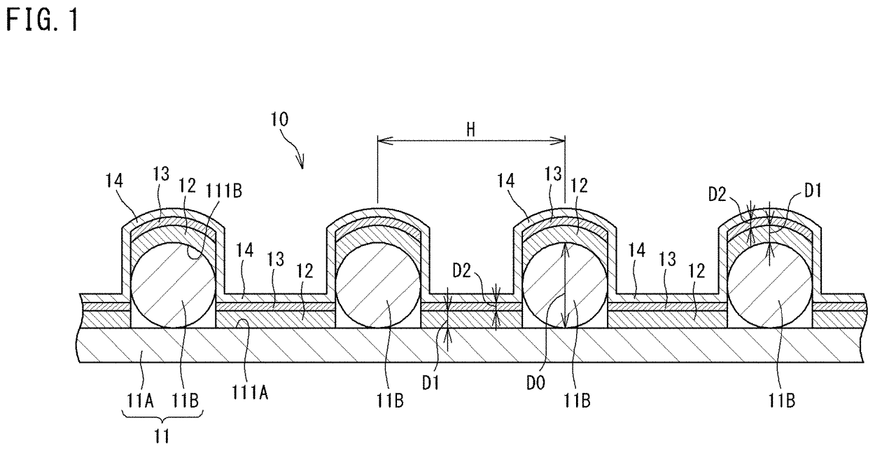

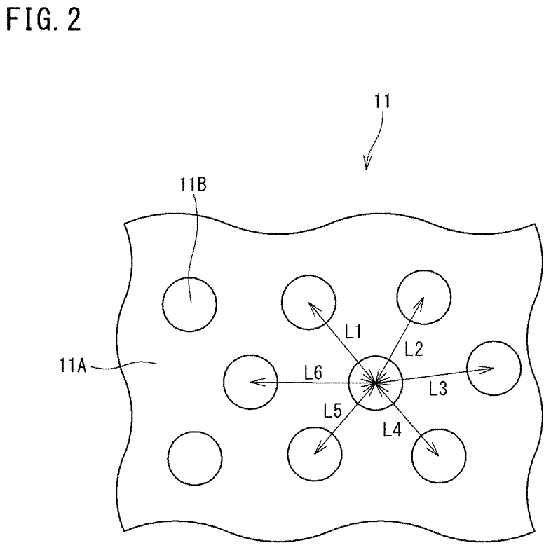

FIG. 1 is a cross-sectional view schematically showing a laminate exhibiting structural color according to a first embodiment. FIG. 2 is a plan view showing a part of a base material layer forming a part of the laminate shown in FIG. 1.

As shown in FIG. 1, the laminate (hereinafter, also referred to as color-developing laminate) 10 exhibiting the structural color according to the present embodiment includes: a base material layer 11; a first layer (hereinafter, also referred to as plasmonic resonance layer) 12 that is laminated on the base material layer 11, that is made of a metal having a high visible light reflectance, and that has a thickness enabling surface plasmonic resonance; and a second layer (hereinafter, also referred to as light absorbing layer) 13 that is laminated on the plasmonic resonance layer 12 and that more easily absorbs visible light than the plasmonic resonance layer 12.

The base material layer 11 includes a plate-like substrate 11A made of glass, a resin such as polystyrene (PS), polypropylene (PP), and polyethylene terephthalate (PET), or the like, and a plurality of projections 11B provided on the upper surface of the substrate 11A. The plurality of projections 11B are composed of a plurality of fine particles, and each fine particle is fixed to the substrate 11A.

The base material layer 11 is not limited to one made of glass or a resin, and may be one made of another material such as a metal. It should be noted that, in the case where the base material layer 11 is made of a metal, it is necessary to interpose a layer made of a dielectric material between the base material layer 11 and the plasmonic resonance layer 12. This is because, in the case where a first layer made of a metal is directly laminated on a base material layer made of a metal, the first layer can exchange free electrons with the base material layer, so that surface plasmonic resonance does not occur at the first layer.

In the base material layer 11, a height D0 of each projection 11B is preferably 100 to 900 nm. Therefore, the diameter of the fine particle forming each projection 11B is preferably 100 to 900 nm. The distance (pitch) between the projections 11B is preferably 1.2 to 2.5 times the height D0 of each projection 11B. The wavelength of light for which plasmonic resonance occurs changes due to a difference in distance (pitch) between the projections 11B, and thus interference color to be developed can be changed by adjusting the pitch within the above range.

This is because, if the above height D0 is within this range, due to surface plasmonic resonance, visible light of some wavelengths are absorbed, and light that has not been absorbed is reflected on the surface of the plasmonic resonance layer (first layer) formed on each of the substrate surface and the projection upper surface, which is suitable for exhibiting structural color due to the effect of interference.

The condition for the case where the light that has not been absorbed is reflected on the surface of the plasmonic resonance layer formed on each of the substrate surface and the projection upper surface and interferes, is, due to Bragg's law,

2·D0·sin θ=m·λ/n.

Here, θ is the angle between incident light and the substrate surface, m is an integer, λ is the wavelength of light, and n is the ambient refractive index.

Since the wavelength of visible light is 380 to 830 nm, when the top of each projection is covered with air, n=1, and when D0 is less than 380 nm or is equal to or larger than 830 nm, the Bragg interference condition cannot be satisfied in the visible light range. In addition, when the top of each projection is covered with a transparent protective layer such as glass, plastic, or the like, a value λ/n obtained by dividing the wavelength of light by the refractive index n of the protective layer becomes a wavelength that contributes to interference or plasmonic resonance. Here, the value of n of glass or plastic is currently about 2 at most, and thus it can be said from the equation that light of at most 1660 nm can contribute to structural color. However, if the height D0 of each projection 11B is excessively large, there are a plurality of wavelengths that satisfy the Bragg interference condition, so that color having high saturation may not be obtained. From these viewpoints, the height D0 of each projection 11B is more preferably 200 to 830 nm.

In the base material layer 11, the plurality of projections 11B are disposed on the surface of the substrate 11A as shown in FIG. 2. The plurality of projections are substantially regularly arranged. Here, the plurality of projections being regularly arranged means that the heights of the respective projections are uniform and the distance between the adjacent projections is uniform.

Here, the plurality of projections may be completely regularly arranged, but, in this case, the developed structural color may be iridescent on the same principle as a diffraction grating.

Therefore, preferably, the plurality of projections are not completely regularly arranged, but are arranged with fluctuation within a predetermined range. Specifically, the plurality of projections preferably have the following fluctuations.

The height fluctuation preferably has a standard deviation of 25 nm or less. The height fluctuation is a fluctuation related to the heights of the projections, and is a value calculated from the heights of a plurality of projections (for example, at randomly extracted 300 locations).

The position fluctuation has a standard deviation of preferably 250 nm or less and more preferably 125 nm or less. The position fluctuation is a fluctuation related to the arrangement positions of the projections. If the projections are ideally arrayed on a hexagonal lattice, all the distances between the particles are equal to each other, and the standard deviation becomes 0. If the arrangement positions have a fluctuation, a fluctuation also occurs in the distances between the particles. Thus, the position fluctuation can be evaluated on the basis of the value of the standard deviation of the distances between the particles.

In the present embodiment, the particle diameters of the above fine particles can be regarded as the heights of the above projections. The average of the particle diameters of the used fine particles may be regarded as the average of the heights of the projections.

Moreover, as for the arrangement of the projections in the color-developing laminate of the present invention, the projections are defined to be substantially regularly arranged, by combining a state of being completely regularly arranged and a state with a certain degree of fluctuation.

The plasmonic resonance layer 12 is laminated on a surface 111A of the substrate 11A and upper surfaces 111B of the projections 11B, and is formed such that substantially the entirety of the upper surface of the base material layer 11 is covered with the plasmonic resonance layer 12 when the color-developing laminate 10 is viewed in plan.

The plasmonic resonance layer 12 is a metal layer that is laminated on the base material layer 11 and that is made of aluminum.

As the metal that forms the plasmonic resonance layer 12, a metal having a negative dielectric constant in the visible light range merely needs to be adopted. Examples of metals having such properties include gold, silver, platinum, titanium, and alloys thereof in addition to aluminum.

Furthermore, if the purpose is not to develop colors in the entire visible light range but to develop a specific color such as red or yellow by using the same metal, a metal that has absorption by direct transition between bands in the visible light range, such as copper and gold, may be used.

The thickness of the plasmonic resonance layer 12 may be any thickness that causes surface plasmonic resonance, but the thickness of the plasmonic resonance layer 12 is preferably 20 to 300 nm. If the thickness is less than 20 nm, the thickness becomes shorter than the electron mean free path, so that electrons come into contact with the surface of the plasmonic resonance layer 12 and scatter/attenuate before traveling the distance of the electron mean free path. On the other hand, if the thickness exceeds 300 nm, the plasmonic resonance layer 12 can be regarded as bulk, so that surface plasmonic resonance becomes hard to occur.

The thickness of the plasmonic resonance layer 12 is more preferably 50 to 150 nm. This is because, when the height of each projection 11B is about 200 to 830 nm, with the plasmonic resonance layer 12 having a thickness in the above range, the color development does not change.

The light absorbing layer 13 is laminated on the plasmonic resonance layer 12 so as to cover the plasmonic resonance layer 12.

The light absorbing layer 13 is a thin layer made of a material that more easily absorbs visible light than the metal that forms the plasmonic resonance layer 12. Since the color-developing laminate 10 includes the light absorbing layer 13, irregular reflection of light at the plasmonic resonance layer 12 can be suppressed, and, as a result, color can be developed with good saturation.

The light absorbing layer 13 is preferably a thin layer made of a material having a reflectance of 75% or less in the visible light range.

Examples of the light absorbing layer 13 include a thin layer made of a metal that more easily absorbs visible light than aluminum or silver, such as germanium and chromium, and a thin layer made of amorphous carbon. In addition, the light absorbing layer 13 may be a thin layer made of a compound of chromium or carbon such as CrO, CrO₂, Cr₃C₂, and C₃N₄.

The thickness of the light absorbing layer 13 is not particularly limited and may be any thickness that allows visible light to pass through the light absorbing layer 13 and reach the plasmonic resonance layer 12.

Here, if the thickness of the light absorbing layer 13 is less than 3 nm, the rate of improvement of saturation by providing the light absorbing layer 13 may be poor. On the other hand, if the thickness of the light absorbing layer 13 exceeds 13 nm, saturation tends to improve, but color derived from the light absorbing layer 13 tends to be developed. Therefore, the thickness of the light absorbing layer 13 is preferably 3 to 13 nm since saturation can be improved without changing hue.

In the case where the light absorbing layer 13 is made of chromium or germanium, the thickness of the light absorbing layer 13 is more preferably 5 to 10 nm.

The color-developing laminate 10 further includes a protective layer 14 laminated on the light absorbing layer 13.

The protective layer 14 is a transparent layer made of glass, and is provided by using a chemical vapor deposition (CVD) method, a sputtering method, a spray coating method, or the like.

As long as the protective layer 14 is a transparent layer, the protective layer 14 does not necessarily need to be a glass layer, and may be, for example, a layer made of a transparent resin composition.

In the color-developing laminate according to the embodiment of the present invention, the above protective layer is an optional member, and does not necessarily have to be provided.

Since the color-developing laminate 10 includes the protective layer 14, the color-developing laminate 10 has more excellent durability.

The color-developing laminate 10 can be produced, for example, through the following steps (1) to (4).

### (1) Production of Base Material Layer 11

First, a fine particle dispersion is prepared by preparing fine particles whose surfaces are modified with a functional group and dispersing the fine particles in water or an aqueous solution of a salt of a strong acid and a strong base. Next, the fine particles are adhered to the surface of the substrate 11A by immersing the substrate 11A in this fine particle dispersion and leaving the substrate 11A therein for a certain time (for example, 1 to 20 hours). Thereafter, the fine particles are fixed to the substrate 11A while this state is maintained. Accordingly, the base material layer 11, in which the projections 11B composed of the fine particles arranged in a hexagonal lattice pattern are formed on the substrate 11A, can be obtained.

The fine particles whose surfaces are modified with the functional group are preferably fine particles whose surfaces are to be charged to the same polarity in a dispersion.

Specific examples of the fine particles whose surfaces are modified with the functional group include latex fine particles or polystyrene fine particles whose surfaces are modified with amidine, and glass (silica) fine particles whose surfaces are modified with a tertiary amine and/or quaternary ammonium cation.

As shown in the following formula (1), amidine ionizes to become positively charged in water. Thus, the fine particles whose surfaces are modified with amidine repel each other in water. As a result, when adhering to the substrate 11A, the fine particles adhere to the substrate 11A in a state of being arranged in a hexagonal lattice pattern. Therefore, by fixing the fine particles that have adhered to the substrate 11A to the substrate 11A, the substrate 11A on which the projections 11B composed of the amidine-modified fine particles are substantially regularly arranged can be obtained.

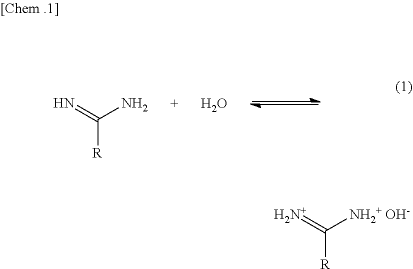

Here, as the method for fixing, to the substrate 11A, the latex fine particles whose surfaces are modified with amidine, for example, a method of irradiating the fine particles with UV light to slightly melt the surfaces of the fine particles, etc., can be adopted.

Moreover, in the case of adhering the fine particles to the substrate 11A, the surface of the substrate 11A is preferably charged, in advance, to a polarity opposite to that of the fine particles.

Accordingly, when the fine particles are adhered to the substrate 11A, an array of the fine particles in a hexagonal lattice pattern is more easily maintained.

As the method for charging the substrate 11A, for example, in the case of negatively charging the surface of the substrate 11A, a method of performing piranha cleaning on a glass substrate and then negatively charging the surface of the glass substrate through RCA-1 cleaning, a method of forming a charged polymer layer on a resin substrate and controlling the potential of the surface of the resin substrate, etc., can be adopted.

In the case of producing the base material layer 11 having the projections 11B arranged on the substrate 11A in this step (1), the heights of the projections 11B can be adjusted by the diameters of the fine particles to be used. At this time, by using fine particles having the same diameter, projections having the same height can be formed.

Moreover, the distance between the projections 11B can be adjusted by the concentration of the aqueous solution of the salt of the strong acid and the strong base in which the fine particles are dispersed. For example, in the case where a dispersion obtained by dispersing amidine-modified fine particles in a KCl aqueous solution is used, the distance between the amidine-modified fine particles changes in response to the KCl concentration. More specifically, the distance between the amidine-modified fine particles linearly changes with respect to a logarithmic concentration change of the KCl concentration. At this time, when the KCl concentration increases, the distance between the fine particle decreases. Thus, by using this characteristic, the distance between the projections 11B (distance between the fine particles) can be controlled.

(2) Next, the plasmonic resonance layer 12 made of aluminum or the like is formed, by a method such as vacuum deposition and sputtering, on the surface of the base material layer 11 at the side where the projections 11B are provided.

The plasmonic resonance layer 12 formed by this method is composed of a metal layer provided in a region that is viewed when the substrate 11A is viewed in plan (a fine particle non-projected region), and a metal layer provided so as to cover about the upper half of each of the fine particles forming the projections 11B.

(3) Next, the light absorbing layer 13 made of chromium, germanium, amorphous carbon, or the like is formed with a predetermined thickness on the plasmonic resonance layer 12. The material of the light absorbing layer 13 is not limited thereto and may be a compound of chromium or carbon.

Similar to the plasmonic resonance layer 12, the light absorbing layer 13 only needs to be formed by a method such as vacuum deposition and sputtering.

Moreover, the light absorbing layer 13 is preferably formed so as to cover the entirety of the upper surface of the plasmonic resonance layer 12. Meanwhile, the light absorbing layer 13 does not necessarily need to be a continuous film.

(4) Next, the transparent protective layer 14 is formed on the entirety of the outermost layer at the side where the light absorbing layer 13 is formed, thereby completing the color-developing laminate.

The protective layer 14 only needs to be formed by using the CVD method described above, or the like, if the protective layer 14 is a protective layer made of glass. Moreover, if the protective layer 14 is a protective layer made of a resin composition, the protective layer 14 only needs to be formed, for example, by applying an uncured resin composition and then curing the uncured resin composition through heating, irradiation with UV light, or the like.

The color-developing laminate 10 of the present embodiment can be produced through such steps.

In the color-developing laminate according to the embodiment of the present invention, the visible color can be adjusted by adjusting the heights of the projections of the base material layer or the distance between the projections.

### Second Embodiment

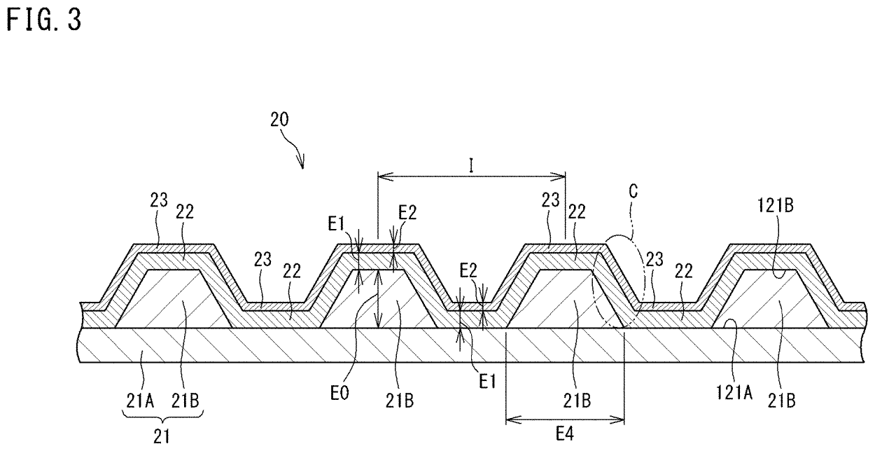

FIG. 3 is a cross-sectional view schematically showing a laminate exhibiting structural color (color-developing laminate) according to a second embodiment.

The color-developing laminate 20 according to the present embodiment is different from the color-developing laminate of the first embodiment in shapes of the projections.

The color-developing laminate 20 includes a base material layer 21, and the base material layer 21 includes a plate-like substrate 21A made of glass, a resin, or the like, and a plurality of projections 21B provided on the upper surface of the substrate 21A. Here, the shape of each of the plurality of projections 21B is a truncated cone.

With the base material layer 21 having the projections 21B having such shapes, the color-developing laminate 20 is obtained by laminating a plasmonic resonance layer 22 and a light absorbing layer 23 on the base material layer 21.

In the color-developing laminate 20 shown in FIG. 3, similar to the color-developing laminate 10 of the first embodiment, a transparent protective layer made of glass or the like may be formed on the light absorbing layer 23 as necessary.

In the color-developing laminate 20 shown in FIG. 3, the plasmonic resonance layer 22 is laminated on the entirety of the upper surface (the exposed surface at the upper side) of the base material layer 21, but the plasmonic resonance layer 22 may be partially formed thereon.

Specifically, for example, the plasmonic resonance layer 22 may be formed on a surface 121A of the substrate 21A and upper surfaces 121B of the truncated cone-shaped projections 21B, and does not have to be formed on slope portions between the surface 121A and the upper surfaces 121B (for example, in a portion C in FIG. 3). Even in the case where the plasmonic resonance layer 22 is partially formed on the upper surface of the base material layer 21 as described above, structural color can be exhibited. In this case, the light absorbing layer 23 only needs to be laminated on the plasmonic resonance layer 22.

In the color-developing laminate 20 of the present embodiment, preferable ranges of a height E0 of each projection 21B, a distance I between the projections 21B, a thickness E1 of the plasmonic resonance layer 22, and a thickness E2 of the light absorbing layer 23 are the same as those of the color-developing laminate 10 of the first embodiment. The height E0 and a diameter E4 of the bottom surface of each projection 21B are substantially equal to each other, and the area of the upper surface of each projection 21B is about 50% of the area of the bottom surface. In the above color-developing laminate, visible color can be adjusted by adjusting the height of each projection of the base material layer or the distance between the projections.

The color-developing laminate 20 according to the present embodiment can be produced by producing a base material layer 21 having a plurality of projections 21B substantially regularly arranged thereon as the base material layer 21, and then forming the plasmonic resonance layer 22 and the light absorbing layer 23 by using a method that is the same as in the first embodiment.

The method for producing the base material layer 21 is not particularly limited. For example, a method, in which a mask is attached onto the substrate 21A, a curable resin composition is printed via the mask, then the printed curable resin composition is cured to form the projections 21B, and then the mask is removed, can be adopted.

### Third Embodiment

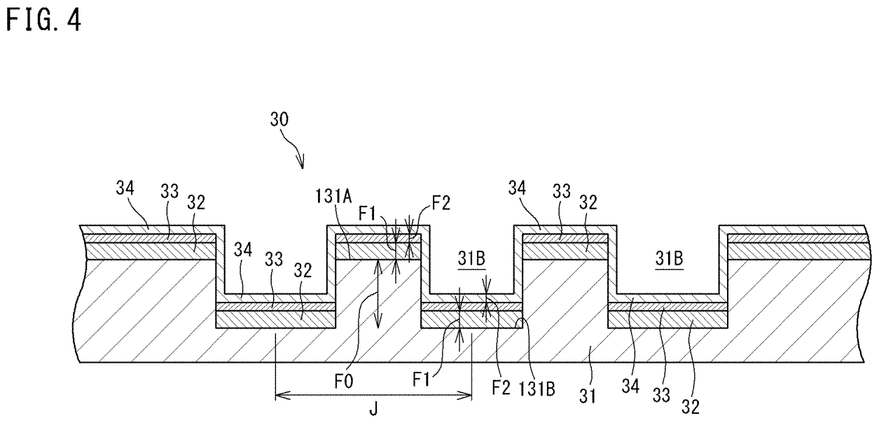

FIG. 4 is a cross-sectional view schematically showing a laminate exhibiting structural color (color-developing laminate) according to a third embodiment.

The color-developing laminate 30 according to the present embodiment is different from the color-developing laminates of the first and second embodiments in that a base material layer has recesses instead of projections.

The color-developing laminate 30 includes a base material layer 31 having a plurality of recesses 31B substantially regularly arranged thereon, a plasmonic resonance layer 32 laminated on the base material layer 31 so as to have a metallic microstructure enabling surface plasmonic resonance, a light absorbing layer 33 laminated on the plasmonic resonance layer 32, and a protective layer 34 provided so as to cover the entirety of the base material layer 31.

The base material layer 31 is made of glass, a resin, or the like and is formed by the plurality of recesses 31B being substantially regularly arranged on one surface of a plate-like substrate. Here, the plurality of recesses 31B each have a cylindrical shape.

A depth F0 of each recess 31B may be any depth that allows the plasmonic resonance layer 32 to have a metallic microstructure enabling surface plasmonic resonance, and the depth F0 is about 100 to 900 nm similar to the height D0 of each projection 11B in the color-developing laminate 10 of the first embodiment.

Moreover, a distance J between the adjacent recesses 31B is also substantially equal to a distance H between the projections 11B in the color-developing laminate 10 of the first embodiment (preferably 1.2 to 2.5 times the height D0 of each projection 11B). Furthermore, the fluctuation of the regular arrangement of the plurality of recesses 31B is also substantially equal to the fluctuation of the plurality of projections 11B in the color-developing laminate 10 of the first embodiment, and, preferably, the depth fluctuation of the recesses 31B has a standard deviation of 25 nm or less and the position fluctuation of the recesses 31B has a standard deviation of 125 nm or less.

Moreover, the diameter of each recess 31B is preferably substantially equal to the height D0 of each projection 11B.

In the color-developing laminate 30, the plasmonic resonance layer 32 is laminated on an upper surface 131A of the base material layer 31 in a region where the recesses 31B are not provided, and on bottom surfaces 131B of the recesses 31B. Accordingly, the plasmonic resonance layer 32 has a metallic microstructure enabling surface plasmonic resonance.

Similar to the thickness D1 of the plasmonic resonance layer 12 in the color-developing laminate 10 of the first embodiment, a thickness F1 of the plasmonic resonance layer 32 is preferably 20 to 300 nm and more preferably 50 to 150 nm.

In the color-developing laminate 30, the light absorbing layer 33 is laminated on the plasmonic resonance layer 32. Similar to the thickness D2 of the light absorbing layer 13 in the color-developing laminate 10 of the first embodiment, a thickness F2 of the light absorbing layer 33 is preferably 3 to 13 nm.

Since the color-developing laminate 30 has such a light absorbing layer 33, the color-developing laminate 30 has excellent saturation.

The color-developing laminate 30 according to the present embodiment can be produced by producing the base material layer 31 having the plurality of recesses 31B and then forming the plasmonic resonance layer 32, the light absorbing layer 33, and the protective layer 34 on the base material layer 31 by using a method that is the same as in the first embodiment.

The method for producing the base material layer 31 is not particularly limited, a conventionally known method can be adopted, and a nanoimprint method can be particularly preferably adopted.

Moreover, in the color-developing laminate, visible color can be adjusted by adjusting the depth of each recess of the base material layer or the distance between the recesses.

### Fourth Embodiment

A color-developing laminate according to the present embodiment is a laminate exhibiting a plurality of different structural colors when being viewed from the same direction.

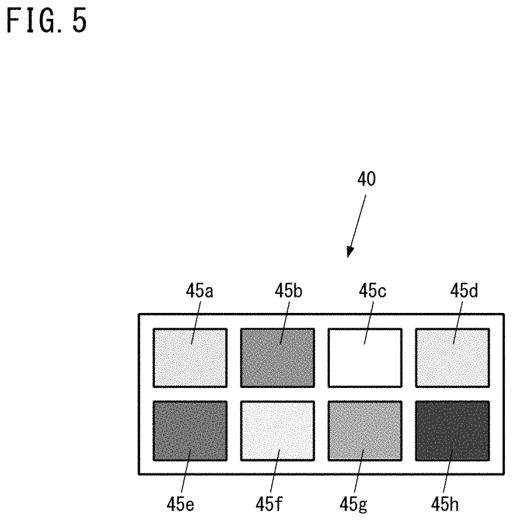

FIG. 5 is a plan view schematically showing the laminate exhibiting structural color according to the fourth embodiment.

As shown in FIG. 5, the color-developing laminate 40 according to the present embodiment has a color-developing surface divided into a plurality of sections 45a to 45h and is formed such that the respective sections 45a to 45h exhibit different structural colors when the color-developing laminate 40 is viewed from the same direction.

The color-developing laminate 40 includes a base material layer having projections arranged thereon, and a plasmonic resonance layer, a light absorbing layer, and a protective layer that are laminated thereon.

In the color-developing laminate 40, as the regularity of arrangement of the above projections (array pitch), different conditions are adopted for the respective sections 45a to 45h, thereby achieving development of different structural colors. More specifically, for each of the sections 45a to 45h, while a configuration that is substantially the same as in the first embodiment is adopted, different conditions are adopted for the heights of the above projections and/or the distance between the projections. This is because these conditions and visible colors correlate to each other.

Since the color-developing laminate 40 can simultaneously exhibit different structural colors, it is possible to express a more complicated design.

### Other Embodiments

The color-developing laminate 10 according to the first embodiment includes a thin layer made of a metal or the like, as the light absorbing layer 13. However, in the color-developing laminate according to each embodiment of the present invention, the above light absorbing layer does not necessarily need to be a film-like thin layer, and may be formed by arranging fine particles made of a metal that more easily absorbs visible light than the above plasmonic resonance layer, such that the fine particles cover the surface of the plasmonic resonance layer. In this case, the diameter of each of the fine particles only needs to be, for example, about 3 to 13 nm.

The reflectance for visible light of the above light absorbing layer only needs to be equal to or less than about 75%.

In the color-developing laminate according to each embodiment of the present invention, in the case where the base material layer has a plurality of projections substantially regularly arranged thereon, the shape of each projection is not limited to a spherical shape (the first embodiment) or a truncated cone shape (the second embodiment), and may be various other shapes such as a hemispherical shape, a cylindrical shape, a prismatic shape, and a truncated pyramid shape, as long as the plasmonic resonance layer can have a structure enabling surface plasmonic resonance when the plasmonic resonance layer is formed on the base material layer.

Moreover, in the case where the base material layer has a plurality of recesses substantially regularly arranged thereon, the shape of each recess is not limited to a cylindrical shape as in the third embodiment, and may be various other shapes such as a hemispherical shape, a prismatic shape, a truncated pyramid shape, and a truncated cone shape, as long as the plasmonic resonance layer can have a structure enabling surface plasmonic resonance when the plasmonic resonance layer is formed on the base material layer.

In the color-developing laminate according to each embodiment of the present invention, in the case where the plasmonic resonance layer is laminated on the upper surfaces of the projections provided to the base material layer (on the upper portions of the projections above 1/2 of the heights of the projections), the plan-view surface area of the first layer (plasmonic resonance layer) laminated on the upper surface of each projection is preferably equal to or greater than about 50% of the surface area of a portion of the projection projected onto the substrate upper surface. If the plan-view surface area of the plasmonic resonance layer laminated on the upper surface of each projection is excessively small, even when the plasmonic resonance layer is formed, light reflected on the base material surface (a portion of the upper surface of the base material layer on which the above projections are not formed) and light reflected on each projection upper surface may not be able to interfere with each other.

As a matter of course, the plasmonic resonance layer may be laminated so as to cover the entireties of the above projections.

In each embodiment of the present invention, the method for producing the base material layer having a plurality of projections or recesses is not limited to the methods adopted in the first to third embodiments.

As another method for producing the above base material layer, for example, in the case of producing a base material layer having projections composed of fine particles, a method, in which a dispersion containing charged fine particles is prepared, the dispersion is applied onto the substrate using an electrostatic coating technique, and the fine particles are fixed to the substrate, can be adopted.

Moreover, for example, a method of forming the above projections on the substrate using a known fine processing technique such as electron beam lithography, immersion lithography, focused ion beam, vacuum deposition, sputtering, chemical vapor deposition (CVD), and atomic layer deposition (ALD), can also be adopted.

Furthermore, for example, a method of forming the projections on the substrate using an inkjet printing technique may be adopted.

The color-developing laminate according to each embodiment of the present invention can be used, in various fields, as a decorative member that itself displays a design or the like or another base material (base material for decoration) for drawing a design. Specifically, the color-developing laminate can be used for, for example, candy bags, plastic bottle beverage labels, refrigerators and other home appliances, car exteriors and interiors, etc. Therefore, the color-developing laminate can be suitably used in, for example, the converting field, etc.

Converting refers to a process in which a material such as paper, plastic film, foil, fiber, and non-woven is processed with an adhesive or a coating agent to produce a high value-added secondary product such as labels, tapes, automotive interior materials, and cushions.

### EXAMPLES

Hereinafter, the present invention will be further specifically described, but the present invention is not limited to the following specific examples. Here, a color-developing laminate of each Test Example was produced, and then the color development state of each color-developing laminate was confirmed.

### Test Example 1

### (1) Preparation of Fine Particle Dispersion A

A fine particle dispersion A was prepared by dispersing 200 μl of a dispersion in water of latex fine particles having a diameter of 300 nm and whose surfaces are modified with amidine (Amidine Latex Beads, manufactured by Thermo Fisher Scientific K.K.) in 100 ml of pure water.

### (2) Production of Base Material Layer

(2a) First, a polystyrene substrate (24 square mm) having a thickness of 0.3 mm was ultrasonically cleaned in a neutral detergent solution (Eye Clean, AS ONE) to remove the oil and grease stains on the polystyrene substrate surface.

Next, the polystyrene substrate subjected to the above cleaning treatment was immersed in the fine particle dispersion A prepared in the above (1) in a ladle and left at 20° C. for 20 hours.
(2b) Thereafter, while the polystyrene substrate was immersed in the fine particle dispersion A in the ladle, stirring was performed in a beaker containing pure water to remove excess latex fine particles that had not adhered to the polystyrene substrate. Then, while the polystyrene substrate was immersed in the pure water, the polystyrene substrate was irradiated, using a spot UV light source (LC6, manufactured by Hamamatsu Photonics K.K.), for 20 seconds with UV light having a wavelength of 365 nm through a 365 nm band-pass filter from a UV light emitting end at a distance of 160 mm, thereby fixing the latex fine particles to the polystyrene substrate.

Next, the pure water in which the polystyrene substrate was immersed was replaced with isopropanol having a surface tension smaller than that of the pure water, then the polystyrene substrate was lifted out of the isopropanol and subsequently subjected to a drying treatment, thereby producing a base material layer in which projections composed of the fine particles were substantially regularly provided on the polystyrene substrate.

In the obtained base material layer, the mode value of the distance between the centers of the adjacent projections was 620 nm.

Regarding the regularity of the projections, the height fluctuation was considered to be equivalent to the fluctuation of the diameters of the fine particles, and the standard deviation thereof was 17 nm. The standard deviation of the position fluctuation was 115 nm.

### (3) Lamination of Plasmonic Resonance Layer

An aluminum layer having a thickness of 50 nm was formed on the surface, of the base material layer produced in the above step (2), at the side where the projections were formed, by vacuum deposition such that the entirety of the surface was covered when being viewed in plan.

A color-developing laminate was completed through such steps.

### Test Example 2

### (1) Preparation of Fine Particle Dispersion B

A fine particle dispersion B was prepared by dispersing 200 μl of a dispersion in water of latex fine particles having a diameter of 400 nm and whose surfaces are modified with amidine (Amidine Latex Beads, manufactured by Thermo Fisher Scientific K.K.) in pure water (100 ml).

### (2) Production of Base Material Layer

A base material layer having projections composed of fine particles was produced by using the same method as Test Example 1, except that the fine particle dispersion B was used instead of the fine particle dispersion A.

In the base material layer obtained here, the mode value of the distance between the centers of the adjacent projections was 862 nm.

Regarding the regularity of the projections, the height fluctuation was considered to be equivalent to the fluctuation of the diameters of the fine particles, and the standard deviation thereof was 13 nm. The standard deviation of the position fluctuation was 163 nm.

### (3) Completion of Color-Developing Laminate

A plasmonic resonance layer was laminated on the base material layer produced in the above step (2) in the same manner as the step (3) of Test Example 1, thereby completing a color-developing laminate.

### Test Example 3

(1) In the same manner as the steps (1) to (3) of Test Example 1, a base material layer having projections composed of latex fine particles having a diameter of 300 nm was produced, and an aluminum layer was laminated as a plasmonic resonance layer on the obtained base material layer.
(2) Lamination of Light Absorbing Layer

Next, a germanium layer having a thickness of 3 nm was further laminated on the aluminum layer laminated in the step (1), by vacuum deposition.

A color-developing laminate was completed through such steps.

### Test Example 4

(1) In the same manner as the steps (1) to (3) of Test Example 2, a base material layer having projections composed of latex fine particles having a diameter of 400 nm was produced, and an aluminum layer was laminated as a plasmonic resonance layer on the obtained base material layer.
(2) Lamination of Light Absorbing Layer

A germanium layer having a thickness of 3 nm was laminated on the aluminum layer laminated in the above step (1) in the same manner as the step (2) of Test Example 3, thereby completing a color-developing laminate.

### Test Example 5

A color-developing laminate was produced in the same manner as Test Example 3, except that the thickness of the germanium layer was changed to 8 nm.

### Test Example 6

A color-developing laminate was produced in the same manner as Test Example 4, except that the thickness of the germanium layer was changed to 8 nm.

### Test Example 7

A color-developing laminate was produced in the same manner as Test Example 3, except that a chromium layer having a thickness of 3 nm was laminated by vacuum deposition instead of the germanium layer in the step (2) of Test Example 3.

### Test Example 8

A color-developing laminate was produced in the same manner as Test Example 4, except that a chromium layer having a thickness of 3 nm was laminated by vacuum deposition instead of the germanium layer in the step (3) of Test Example 4.

### (Evaluation of Coloration State)

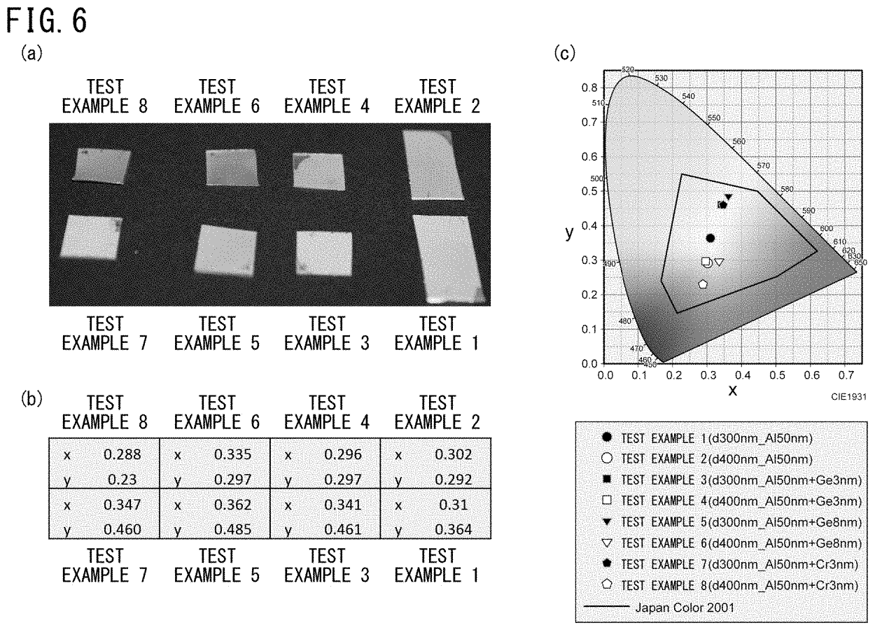

The coloration states of the color-developing laminates produced in Test Examples 1 to 8 are shown in FIG. 6.

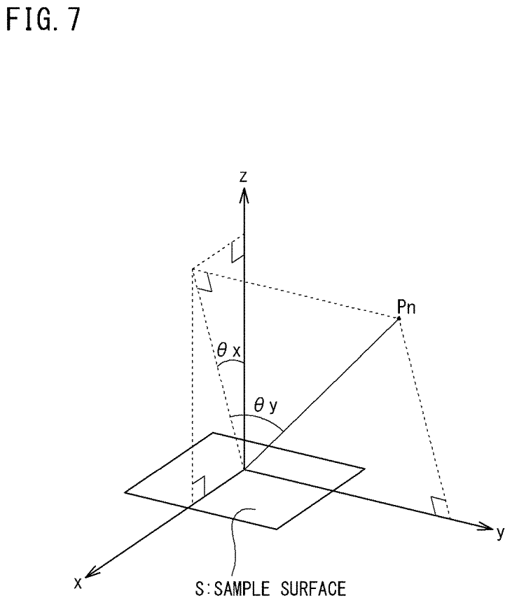

FIG. 6(a) is a color photograph obtained by photographing each color-developing laminate from a predetermined position (see FIG. 7).

FIG. 6(b) is a table showing measured values of chromaticity in FIG. 6(a). The chromaticity is a value obtained by reading the RGB value of each color-developing laminate in the color photograph with Photoshop (manufactured by Adobe Systems Incorporated) and converting the value into a value in the XYZ color system.

FIG. 6(c) is a diagram showing results of the chromaticity in FIG. 6(b) being plotted on a CIE 1931 chromaticity diagram. In the diagram, the polygon indicates the color gamut defined by Japan Color 2001.

FIG. 7 is a diagram for explaining a position for taking a color photograph in evaluation of the Test Examples.

As shown in FIG. 7, for the color-developing laminate, an x-axis and a y-axis were defined within a sample surface S, a z-axis was defined in a line normal to the sample surface S, and a position tilted at an angle θₓ in the x direction and at an angle θ_{y} in the y direction was defined as a point Pn.

Moreover, in taking the color photograph shown in FIG. 6(a), standard illuminant D65 was applied from a position P1 tilted at 0° in the x direction and at 30° in the y direction, and each color-developing laminate was photographed from a position P2 tilted at 0° in the x direction and 45° in the y direction.

As shown in FIG. 6, the color-developing laminates (Test Examples 3 to 8) having a metallic microstructure enabling surface plasmonic resonance and in which the light absorbing layer was laminated on the plasmonic resonance layer exhibiting structural color, had better saturation than the color-developing laminates (Test Examples 1 and 2) in which a light absorbing layer was not laminated. This can be understood from the fact that, in FIG. 6, the plotted positions of the color-developing laminates in which the light absorbing layer was laminated are shifted outward of the plotted positions of the color-developing laminates in which a light absorbing layer was not laminated.

### Test Example 9

### (1) Preparation of Fine Particle Dispersion C

A fine particle dispersion C was prepared by dispersing 200 μl of a dispersion in water of latex fine particles having a diameter of 200 nm and whose surfaces are modified with amidine (Amidine Latex Beads, manufactured by Thermo Fisher Scientific K.K.) in pure water (100 ml).

### (2) Production of Base Material Layer

(2a) First, a glass substrate (50 square mm) having a thickness of 1 mm was cleaned with a piranha solution (a mixed solution having a volume ratio, concentrated sulfuric acid:30% hydrogen peroxide water=3:1). Subsequently, the surface of the glass substrate was negatively charged by cleaning with an RCA-1 solution (a mixed solution having a volume ratio, pure water:ammonia:hydrogen peroxide=5:1:1).

Next, the glass substrate subjected to the above cleaning treatment was immersed in the fine particle dispersion C prepared in the above (1) in a ladle and left at 5° C. for 20 hours.
(2b) Thereafter, while the glass substrate was immersed in the fine particle dispersion C in the ladle, stirring was performed in a beaker containing pure water to remove excess latex fine particles that had not adhered to the glass substrate. Then, while the glass substrate was immersed in the pure water, the glass substrate was irradiated, using a spot UV light source (LC6, Hamamatsu Photonics K.K.), for 20 seconds with UV light having a wavelength of 365 nm through a 365 nm band-pass filter from a UV light emitting end at a distance of 160 mm, thereby fixing the latex fine particles to the glass substrate.

Next, the pure water in which the glass substrate was immersed was replaced with isopropanol having a surface tension smaller than that of the pure water, then the glass substrate was lifted out of the isopropanol and subsequently subjected to a drying treatment, thereby producing a base material layer in which projections composed of the fine particles were substantially regularly provided on the glass substrate.

In the obtained base material layer, the mode value of the distance between the centers of the adjacent projections was 424 nm.

Regarding the regularity of the projections, the height fluctuation was considered to be equivalent to the fluctuation of the diameters of the fine particles, and the standard deviation thereof was 10 nm. The standard deviation of the position fluctuation was 103 nm.

### (3) Lamination of Plasmonic Resonance Layer

An aluminum layer having a thickness of 50 nm was formed on the surface, of the base material layer produced in the above step (2), at the side where the projections were formed, by vacuum deposition such that the entirety of the surface was covered when being viewed in plan.

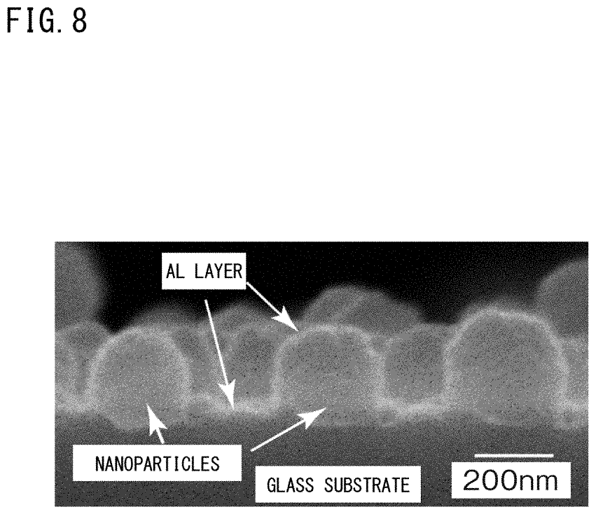

FIG. 8 shows an electron micrograph of the member produced in this step.

### (4) Formation of Protective Layer

Finally, a protective layer covering the entirety of the surface of the base material layer at the side where the plasmonic resonance layer was formed was provided by pyrolyzing tetraethyl orthosilicate (TEOS) according to the following reaction formula using plasma-enhanced chemical vapor deposition to form a silica layer.

Si(OC₂H₅)₄→SiO₂+2O(C₂H₅)₂

A color-developing laminate was completed through such steps.

### Test Example 10

(1) In the same manner as the steps (1) to (3) of Test Example 9, a base material layer having projections composed of latex fine particles was produced, and then an aluminum layer was laminated as a plasmonic resonance layer on the obtained base material layer.
(2) Lamination of Light Absorbing Layer

A chromium layer having a thickness of 10 nm was laminated as a light absorbing layer on the aluminum layer laminated in the above step (1), by vacuum deposition.
(3) Formation of Protective Layer

A protective layer was laminated on the light absorbing layer formed in the above step (2) in the same manner as the step (4) of Test Example 9, thereby completing a color-developing laminate.

### Test Example 11

A color-developing laminate was produced in the same manner as Test Example 9, except that a base material layer was produced by using a fine particle dispersion D prepared by the following method, instead of the fine particle dispersion C.

In the base material layer produced in this Test Example, the mode value of the distance between the centers of the adjacent projections was 620 nm.

Regarding the regularity of the projections, the height fluctuation was considered to be equivalent to the fluctuation of the diameters of the fine particles, and the standard deviation thereof was 17 nm. The standard deviation of the position fluctuation was 115 nm.

Preparation of Fine Particle Dispersion D

A fine particle dispersion D was prepared by dispersing 200 μl of a dispersion in water of latex having a diameter of 300 nm and whose surfaces are modified with amidine (Amidine Latex Beads, manufactured by Thermo Fisher Scientific K.K.) in pure water (100 ml).

### Test Example 12

A color-developing laminate was produced in the same manner as Test Example 10 except that a base material layer was produced by using the fine particle dispersion D prepared by the above-described method, instead of the fine particle dispersion C.

The base material layer produced in this Test Example is the same as the base material layer produced in Test Example 11.

### Test Example 13

A color-developing laminate was produced in the same manner as Test Example 9, except that a base material layer was produced by using a fine particle dispersion E prepared by the following method, instead of the fine particle dispersion C.

In the base material layer produced in this Test Example, the mode value of the distance between the centers of the adjacent projections was 862 nm.

Regarding the regularity of the projections, the height fluctuation was considered to be equivalent to the fluctuation of the diameters of the fine particles, and the standard deviation thereof was 13 nm. The standard deviation of the position fluctuation was 163 nm.

Preparation of Fine Particle Dispersion E

A fine particle dispersion E was prepared by dispersing 200 μl of a dispersion in water of latex having a diameter of 400 nm and whose surfaces are modified with amidine (Amidine Latex Beads, manufactured by Thermo Fisher Scientific K.K.) in pure water (100 ml).

### Test Example 14

A color-developing laminate was produced in the same manner as Test Example 10 except that a base material layer was produced by using the fine particle dispersion E prepared by the above-described method, instead of the fine particle dispersion C.

The base material layer produced in this Test Example is the same as the base material layer produced in Test Example 13.

### Test Example 15

A color-developing laminate was produced in the same manner as Test Example 9, except that a base material layer was produced by using a fine particle dispersion F prepared by the following method, instead of the fine particle dispersion C.

In the base material layer produced in this Test Example, the mode value of the distance between the centers of the adjacent projections was 937 nm.

Regarding the regularity of the projections, the height fluctuation was considered to be equivalent to the fluctuation of the diameters of the fine particles, and the standard deviation thereof was 13 nm. The standard deviation of the position fluctuation was 214 nm.

Preparation of Fine Particle Dispersion F

A fine particle dispersion F was prepared by dispersing 200 μl of a dispersion in water of latex fine particles having a diameter of 500 nm and whose surfaces are modified with amidine (Amidine Latex Beads, manufactured by Thermo Fisher Scientific K.K.) in pure water (100 ml).

### Test Example 16

A color-developing laminate was produced in the same manner as Test Example 10 except that a base material layer was produced by using the fine particle dispersion F prepared by the above-described method, instead of the fine particle dispersion C.

The base material layer produced in this Test Example is the same as the base material layer produced in Test Example 15.

### (Evaluation of Coloration State)

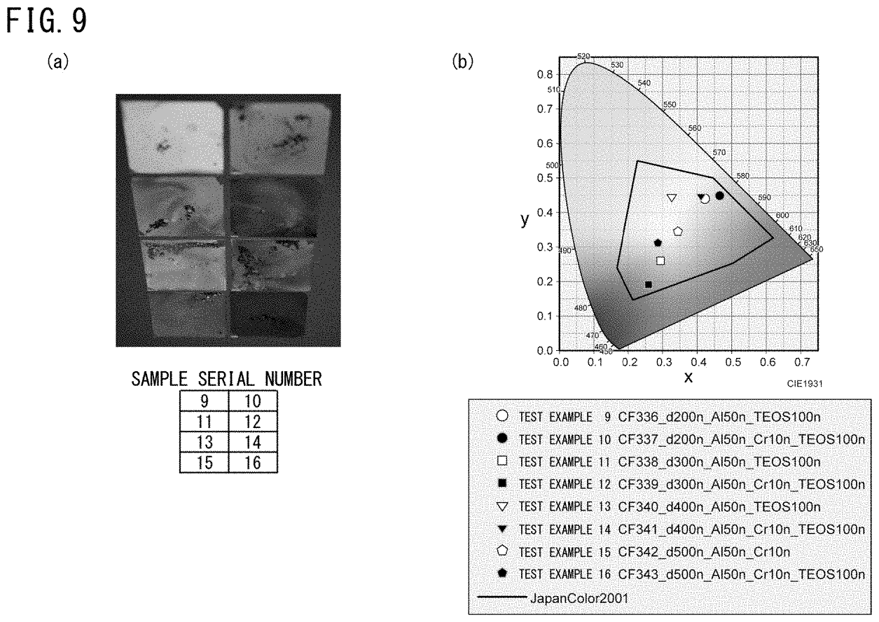

The coloration states of the color-developing laminates produced in Test Examples 9 to 16 are shown in FIG. 9.

Similar to FIG. 6(a), FIG. 9(a) is a color photograph obtained by applying standard illuminant D65 from a position tilted at 0° in the x direction and at 30° in the y direction and photographing each color-developing laminate from a position tilted at 0° in the x direction and at 45° in the y direction.

FIG. 9(b) is a diagram showing results of the chromaticity in FIG. 9(a) being plotted on a CIE 1931 chromaticity diagram. In the diagram, the polygon indicates the color gamut defined by Japan Color 2001.

As shown in FIG. 9, the color-developing laminates (Test Examples 10, 12, 14, and 16) having a metallic microstructure enabling surface plasmonic resonance and in which the light absorbing layer was laminated on the plasmonic resonance layer exhibiting structural color, had better saturation than the color-developing laminates (claims 9, 11, 13, and 15) in which a light absorbing layer was not laminated. This point was the same even when a protective layer (transparent glass layer) is provided at the outermost layer.

### Test Examples 17 and 18

### (1) Preparation of Fine Particle Dispersion G

A fine particle dispersion G was prepared by dispersing 100 μl of a dispersion of silica fine particles having a diameter of 300 nm and whose surfaces are modified with quaternary ammonium cation (Sicastar NR3+ modified, manufactured by Micromod Partikeltechnologie GmbH) in 5 ml of pure water.

### (2) Production of Base Material Layer

(2a) First, a polyethylene terephthalate substrate (25 square mm) having a thickness of 50 μm was ultrasonically cleaned in a neutral detergent solution (Ai-clean, AS ONE) to remove the oil and grease stains on the polyethylene terephthalate substrate surface.

Next, the polyethylene terephthalate substrate subjected to the above cleaning treatment was immersed in the fine particle dispersion G prepared in the above (1) in a ladle and left at 20° C. for 3 hours.
(2b) Thereafter, while the polyethylene terephthalate substrate was immersed in the fine particle dispersion G in the ladle, the polyethylene terephthalate substrate was irradiated, using a spot UV light source (LC6, manufactured by Hamamatsu Photonics K.K.), for 45 seconds with UV light having a wavelength of 365 nm through a 365 nm band-pass filter from a UV light emitting end at a distance of 160 mm, thereby fixing the silica fine particles to the polyethylene terephthalate substrate.

Next, while the polyethylene terephthalate substrate was immersed in the fine particle dispersion G in the ladle, stirring was performed in a beaker containing pure water to remove excess silica fine particles that had not been fixed to the polyethylene terephthalate substrate.

Next, the pure water in which the polyethylene terephthalate substrate was immersed was replaced with isopropanol having a surface tension smaller than that of the pure water, then the polyethylene terephthalate substrate was lifted out of the isopropanol and subsequently subjected to a drying treatment, thereby producing a base material layer in which projections composed of the fine particles were substantially regularly provided on the polyethylene terephthalate substrate.

In the obtained base material layer, the mode value of the distance between the centers of the adjacent projections was 680 nm.

Regarding the regularity of the projections, the height fluctuation was considered to be equivalent to the fluctuation of the diameters of the fine particles, and the standard deviation thereof was 14 nm. The standard deviation of the position fluctuation was 110 nm.

### (3) Lamination of Plasmonic Resonance Layer

An aluminum layer having a thickness of 100 nm was formed on the surface, of the base material layer produced in the above step (2), at the side where the projections were formed, by vacuum deposition such that the entirety of the surface was covered when being viewed in plan.

Thereafter, the obtained laminate was divided into two regions by a diagonal line. Next, one of the two divided regions was covered with aluminum foil, and the next step (4) was performed in that state.

### (4) Lamination of Light Absorbing Layer

A carbon layer having a thickness of about 100 Å was further laminated on the upper surface (the surface at the side where the plasmonic resonance layer was formed) of the laminate in which one of the two regions obtained by the division by the diagonal line was covered with the aluminum foil, by using a carbon coater (JEC-560, manufactured by JEOL Ltd.).

Thereafter, the aluminum foil was removed.

### (5) Formation of Protective Layer

A protective layer covering the entirety of the upper surface of the laminate was provided by heating and pressure-bonding laminate films (business card size laminate films LZ-NC100 with a thickness of 100 μm, manufactured by Iris Ohyama Inc.) between which the laminate from which the aluminum foil had been removed was interposed, at 160° C. and 0.40 m/s using a pack-type laminating machine (LPD3226, Meister 6, manufactured by Fujipla).

Through such steps, a test piece, in which a color-developing laminate (Test Example 17) not having a light absorbing layer was produced in one of the regions obtained by the division by the diagonal line and a color-developing laminate (Test Example 18) having a light absorbing layer was produced in the other of the regions obtained by the division by the diagonal line, was prepared.

### Test Examples 19 and 20

A test piece, in which a color-developing laminate (Test Example 19) not having a light absorbing layer and a color-developing laminate (Test Example 20) having a light absorbing layer were integrated with each other, was prepared in the same manner as Test Examples 17 and 18, except that a fine particle dispersion H prepared by the following method was used instead of the fine particle dispersion G.

In the base material layer produced in this Test Example, the mode value of the distance between the centers of the adjacent projections was 680 nm.

Regarding the regularity of the projections, the height fluctuation was considered to be equivalent to the fluctuation of the diameters of the fine particles, and the standard deviation thereof was 16 nm. The standard deviation of the position fluctuation was 339 nm.

Preparation of Fine Particle Dispersion H

A fine particle dispersion H was prepared by dispersing 100 μl of dispersion of silica fine particles having a diameter of 400 nm and whose surfaces are modified with quaternary ammonium cation (Sicastar NR3+ modified, manufactured by Micromod Partikeltechnologie GmbH) in 5 ml of pure water.

### Test Examples 21 and 22

A test piece, in which a color-developing laminate (Test Example 21) not having a light absorbing layer and a color-developing laminate (Test Example 22) having a light absorbing layer were integrated with each other, was prepared in the same manner as Test Examples 17 and 18, except that a fine particle dispersion I prepared by the following method was used instead of the fine particle dispersion G.

In the base material layer produced in this Test Example, the mode value of the distance between the centers of the adjacent projections was 905 nm.

Regarding the regularity of the projections, the height fluctuation was considered to be equivalent to the fluctuation of the diameters of the fine particles, and the standard deviation thereof was 13 nm. The standard deviation of the position fluctuation was 75 nm.

Preparation of Fine Particle Dispersion I

A fine particle dispersion I was prepared by dispersing 100 μl of a dispersion of silica fine particles having a diameter of 500 nm and whose surfaces are modified with quaternary ammonium cation (Sicastar NR3+ modified, manufactured by Micromod Partikeltechnologie GmbH) in 5 ml of pure water.

### Test Examples 23 and 24

A test piece, in which a color-developing laminate (Test Example 23) not having a light absorbing layer and a color-developing laminate (Test Example 24) having a light absorbing layer were integrated with each other, was prepared in the same manner as Test Examples 17 and 18, except that a fine particle dispersion J prepared by the following method was used instead of the fine particle dispersion G.

In the base material layer produced in this Test Example, the mode value of the distance between the centers of the adjacent projections was 895 nm.

Regarding the regularity of the projections, the height fluctuation was considered to be equivalent to the fluctuation of the diameters of the fine particles, and the standard deviation thereof was 18 nm. The standard deviation of the position fluctuation was 53 nm.

Preparation of Fine Particle Dispersion J

A fine particle dispersion J was prepared by dispersing 100 μl of a dispersion of silica fine particles having a diameter of 600 nm and whose surfaces are modified with quaternary ammonium cation (Sicastar NR3+ modified, manufactured by Micromod Partikeltechnologie GmbH) in 5 ml of pure water.

### (Evaluation of Coloration State)

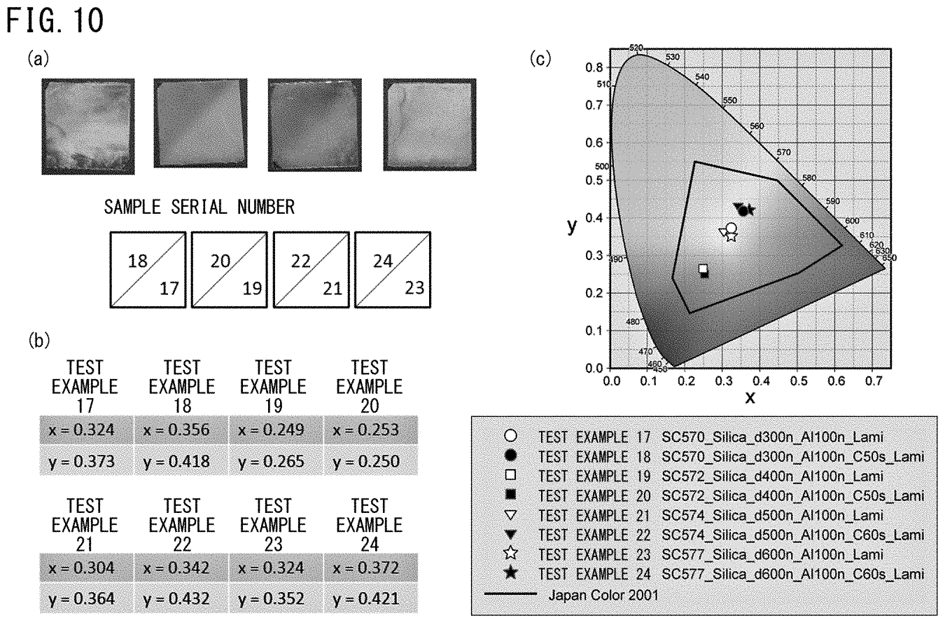

The coloration states of the color-developing laminates produced in Test Examples 17 to 24 are shown in FIG. 10.

FIG. 10(a) is a color photograph obtained by photographing each color-developing laminate from a predetermined position. Specifically, similar to FIG. 6(a), standard illuminant D65 was applied from a position P1 tilted at 0° in the x direction and at 30° in the y direction, and each color-developing laminate was photographed from a position P2 tilted at 0° in the x direction and at 45° in the y direction (see FIG. 7).

FIG. 10(b) is a table showing measured values of chromaticity in FIG. 10(a). The chromaticity is a value obtained by reading the RGB value of each color-developing laminate in the color photograph with Photoshop (manufactured by Adobe Systems Incorporated) and converting the value into a value in the XYZ color system.

FIG. 10(c) is a diagram showing results of the chromaticity in FIG. 10(b) being plotted on a CIE 1931 chromaticity diagram. In the diagram, the polygon indicates the color gamut defined by Japan Color 2001.

As shown in FIG. 10, the color-developing laminates (Test Examples 18, 20, 22, and 24) having a metallic microstructure enabling surface plasmonic resonance and in which the light absorbing layer was laminated on the plasmonic resonance layer exhibiting structural color, had better saturation than the color-developing laminates (Test Examples 17, 19, 21, and 23) in which a light absorbing layer was not laminated. This feature was the same even when a protective layer (transparent resin layer) is provided at the outermost layer.

### REFERENCE SIGNS LIST

10, 20, 30, 40 laminate exhibiting structural color (color-developing laminate)

11, 21, 31 base material layer

11A, 21A substrate

11B, 21B projection

12, 22, 32 first layer (plasmonic resonance layer)

13, 23, 33 second layer (light absorbing layer)

14, 34 protective layer

31B recess

45a, 45b, 45c, 45d, 45e, 45f, 45g, 45h section

111A, 121A surface of substrate

111B, 121B upper surface of projection

131A upper surface of base material layer

131B bottom surface of recess

D0, E0 height of projection

D1, E1, F1 thickness of plasmonic resonance layer

D2, E2, F2 thickness of light absorbing layer

F0 depth of recess

H, I distance between projections

J distance between recesses

1. (canceled)

2. (canceled)

3. (canceled)

4. (canceled)

5. (canceled)

6. (canceled)

7. (canceled)

8. (canceled)

9. (canceled)

10. A laminate exhibiting structural color, the laminate comprising:
a base material layer having a plurality of projections or a plurality of recesses substantially regularly arranged thereon;
a first layer that is a metal layer laminated on the base material layer so as to have a metallic microstructure enabling surface plasmonic resonance; and
a second layer laminated on the first layer and made of a material that more easily absorbs visible light than a metal forming the first layer,
wherein a thickness of the second layer is 3 to 13 nm.

11. The laminate exhibiting the structural color according to claim 10, wherein a height of each projection or a depth of each recess of the base material is 100 to 900 nm.

12. The laminate exhibiting the structural color according to claim 10, wherein
the plurality of projections each have a spherical shape, and
each projection is composed of a fine particle having a diameter of 100 to 900 nm.

13. The laminate exhibiting the structural color according to claim 10, wherein a thickness of the first layer is 20 to 300 nm.

14. The laminate exhibiting the structural color according to claim 10, wherein the first layer is made of aluminum, gold, silver, copper, or titanium, or an alloy thereof.

15. The laminate exhibiting the structural color according to claim 10, wherein the second layer has a reflectance for visible light of 75%or less.

16. The laminate exhibiting the structural color according to claim 10, wherein the second layer is made of germanium, chromium, carbon, or a compound of chromium or carbon.

17. The laminate exhibiting the structural color according to claim 10, wherein a transparent protective layer is further provided at an outermost layer.
